(19) United States
(12) Patent Application Publication
(10) Pub. No.: US 2020/0185645 A1
(43) Pub. Date: Jun. 11, 2020

(54) ACTIVE MATRIX ORGANIC LIGHT EMITTING DIODE PANEL

(71) Applicant: Wuhan China Star Optoelectronics Semincoductor Display Technology Co., Ltd., Wuhan (CN)

(72) Inventor: Shuang E, Wuhan (CN)

(73) Assignee: Wuhan China Star Optoelectronics Semiconductor Display Technology Co., Ltd., Wuhan (CN)

(21) Appl. No.: 16/477,888

(22) PCT Filed: Mar. 5, 2019
(86) PCT No.: PCT/CN2019/076917

§ 371 Date: Jul. 14, 2019

(30) Foreign Application Priority Data
Dec. 6, 2018 (CN) 201811486981.X

(51) Int. Cl. H01L 51/52; H01L 51/00; H01L 27/32; H01L 51/56

(52) U.S. Cl. CPC H01L 51/5253; H01L 51/0097; H01L 27/323; H01L 51/5281; H01L 2251/558; H01L 51/56; H01L 27/3244; H01L 2251/5338; H01L 51/5246

(57) ABSTRACT

The present disclosure provides an AMOLED panel provided with a hydrogel layer on a bent portion between a first backing plate and a second backing plate. The hydrogel layer can increase structural strength and toughness of a fillet of the bent portion formed by folding the bent portion, Therefore, the bent portion can maintain its structural strength and shape when it is folded and is not easily deformed, broken or cracked, thereby improving the product quality and durability of the AMOLED panel.

### FIELD OF INVENTION

The present disclosure relates to a field of active matrix organic light emitting diode (AMOLED) panel technology, and particularly to an AMOLED panel whose bent portion is strengthened.

### BACKGROUND

Compared with traditional liquid crystal display screens, active matrix organic light emitting diode (AMOLED) screens have advantages of fast response times, self-illumination, wide viewing angles, good display effect, and low power consumption. In order to reduce product size, AMOLED panels typically require a pad bending process that is to fold a flexible printed circuit (FPC) along a bent portion. After the FPC is folded, the bent portion forms a fillet. The fillet will affect product quality. This is because the bent portion is subjected to larger stress, so that the fillet of the bent portion is prone to quality problems such as deformation or breakage during product production and use.

Therefore, it is necessary to propose a new AMOLED panel to solve the quality problem that the existing AMOLED panels are prone to deformation or breakage at the bent portions thereof.

### SUMMARY OF DISCLOSURE

To solve the aforementioned technical problem, the present disclosure provides an AMOLED panel capable of solving the problem that the existing AMOLED panels are prone to deformation or breakage at the bent portions thereof.

The present disclosure provides an AMOLED panel, comprising:

an insulating substrate layer having a bent portion;

a first backing plate and a second backing plate disposed on the insulating substrate layer and separated by the bent portion;

a hydrogel coated on the bent portion between the first backing plate and the second backing plate;

an organic light emitting diode (OLED) layer disposed on a surface of the insulating substrate layer opposite to the surface on which the first backing plate and the second backing plate are disposed;

a touch plate optical clear adhesive layer disposed on a surface of the OLED layer opposite to the surface on which the insulating substrate layer is disposed;

a touch plate layer disposed on a surface of the touch plate optical clear adhesive layer opposite to the surface on which the OLED layer is disposed;

a polarizer layer disposed on a surface of the touch plate layer opposite to the surface on which the touch plate optical clear adhesive layer is disposed;

an optical clear adhesive layer disposed on a surface of the polarizer layer opposite to the surface on which the touch plate layer is disposed; and

a cover glass layer disposed on a surface of the optical clear adhesive layer opposite to the surface on which the polarizer layer is disposed.

In an embodiment, an area of the second backing plate is less than that of the first backing plate, and when the insulating substrate layer is folded at the bent portion, an orthographic projection area of the second backing plate all falls on a surface of the first backing plate facing the second backing plate.

In an embodiment, when the bent portion is in a folded state, its bending angle is 180 degrees.

In an embodiment, the hydrogel layer has a thickness of 20-50 μm.

In an embodiment, the insulating substrate layer is made of a polyimide (PI) material.

The present disclosure further provides a method of manufacturing an AMOLED panel, comprising:

Step 1: uniformly coating the hydrogel layer on the bent portion between the first backing plate and the second backing plate;

Step 2: irradiating the hydrogel layer with ultraviolet to solidify the hydrogel layer; and

Step 3: folding the first backing plate and the second backing plate deposited on the insulating substrate layer at the bent portion, such that a bending angle of the bent portion is 180 degrees when the bent portion is in a folded state.

In an embodiment, an area of the second backing plate is less than that of the first backing plate, and when the insulating substrate layer is folded at the bent portion, an orthographic projection area of the second backing plate all falls on a surface of the first backing plate facing the second backing plate.

The present disclosure provides an AMOLED panel provided with a hydrogel layer on a bent portion between a first backing plate and a second backing plate. The hydrogel layer can increase structural strength and toughness of a fillet of the bent portion formed by folding the bent portion, Therefore, the bent portion can maintain its structural strength and shape when it is folded and is not easily deformed, broken or cracked, thereby improving the product quality and durability of the AMOLED panel.

### BRIEF DESCRIPTION OF DRAWINGS

In order to more clearly illustrate the technical solutions in the embodiments of the present disclosure, a brief description of accompanying drawings used in the description of the embodiments of the present disclosure will be given below. Obviously, the accompanying drawings in the following description are merely some embodiments of the present disclosure. For those skilled in the art, other drawings may be obtained from these accompanying drawings without creative labor.

FIG. 1 is a structural schematic diagram of an AMOLED panel according to an embodiment of the present disclosure.

FIG. 2 is a cross-sectional view of the AMOLED panel according to the embodiment of the present disclosure taken along a line A-A shown in FIG. 1.

FIG. 3 is a structural schematic diagram showing that a bent portion of the AMOLED panel according to the embodiment of the present disclosure is folded.

FIG. 4 is a schematic diagram of a fillet formed by folding bent portion 20 of the AMOLED panel according to the embodiment of the present disclosure.

FIG. 5 is a schematic diagram showing that the bent portion of the AMOLED panel according to the embodiment of the present disclosure is coated with a hydrogel.

FIG. 6 is a schematic diagram showing that the hydrogel coated on the bent portion of the AMOLED panel according to the embodiment of the present disclosure is cured by an ultraviolet (UV) lamp.

### DETAILED DESCRIPTION

Reference throughout this specification to “an embodiment” means that a particular feature, structure, or characteristic described in connection with the indicated embodiment is included in at least one embodiment of the present disclosure. The same terms appearing in different places in the specification are not necessarily limited to the same embodiments, but should be understood as independent or alternative embodiments to other embodiments. In view of the technical solutions disclosed in the embodiments of the present disclosure, those skilled in the art should understand that the embodiments described in the present disclosure may have other combinations or modifications in accordance with the embodiments of the present disclosure.

The following description of various embodiments of the present disclosure with reference to the accompanying drawings is used to illustrate specific embodiments that can be practiced. Directional terms mentioned in the present disclosure, such as “above”, “below”, “front”, “rear”, “left”, “right”, “inside”, “outside”, “side”, “vertical”, “horizontal”, etc., are merely used to indicate the direction of the accompanying drawings. Therefore, the directional terms are used for illustrating and understanding the present disclosure rather than limiting the present disclosure.

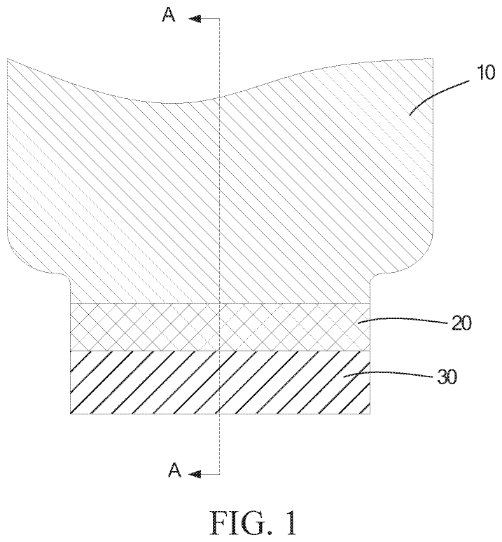

FIG. 1 is a structural schematic diagram of an active matrix organic light emitting diode (AMOLED) panel according to an embodiment of the present disclosure. A first backing plate 10, a bent portion 20, and a second backing plate 30 are disposed on an insulating substrate layer of the AMOLED panel. The second backing plate 30 is coupled to the first backing plate 10 by the bent portion 20. An area of the second backing plate 30 is less than that of the first backing plate 10, and when the insulating substrate layer is folded, an orthographic projection area of the second backing plate 30 all falls on a surface of the first backing plate 10 facing the second backing plate 30. The first backing plate 10 and the second backing plate 30 have a thickness of 95 μm.

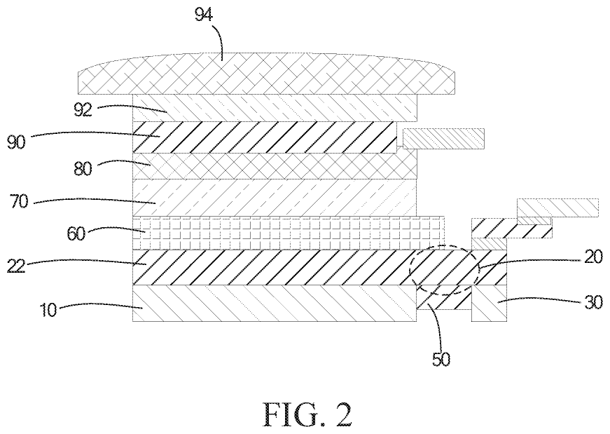

FIG. 2 is a cross-sectional view of the AMOLED panel according to the embodiment of the present disclosure taken along a line A-A shown in FIG. 1. The first backing plate 10 and the second backing plate 30 are disposed on the insulating substrate layer 22 and separated by the bent portion 20. The bent portion 20 between the first backing plate 10 and the second backing plate 30 is coated with a hydrogel layer 50. When the second backing plate 30 and the first backing plate 10 are in a folded state, the hydrogel layer 50 can increase structural strength of the bent portion 20. The insulating substrate layer 22 may be made of a polyimide (PI) material. The hydrogel layer 50 may be made of a photocurable material such as an ultraviolet (UV) curable material. A thickness of the hydrogel layer 50 may be set between 20 μm and 50 μm. A width of the hydrogel layer 50 may be the same as the width of the bent portion 20. The hydrogel layer 50 can support and protect the bent portion 20. An organic light emitting diode (OLED) layer 60 is disposed on a surface of the insulating substrate layer 22 opposite to the surface on which the first backing plate 10 and the second backing plate 30 are disposed. The OLED layer 60 further comprises a thin film transistor layer (TFT layer) and a thin film encapsulation layer (TFE layer). A touch plate optical clear adhesive layer (TP OCA layer) 70 is disposed on a surface of the OLED layer 60 opposite to the surface on which the insulating substrate layer 22 is disposed. A touch plate layer (TP layer) 80 is disposed on a surface of the touch plate optical clear adhesive layer 70 opposite to the surface on which the OLED layer 60 is disposed. A polarizer layer (POL layer) 90 is disposed on a surface of the touch plate layer 80 opposite to the surface on which the touch plate optical clear adhesive layer 70 is disposed. An optical clear adhesive layer 92 disposed on a surface of the polarizer layer 90 opposite to the surface on which the touch plate layer is disposed 80. A cover glass layer 94 disposed on a surface of the optical clear adhesive layer 92 opposite to the surface on which the polarizer layer 90 is disposed.

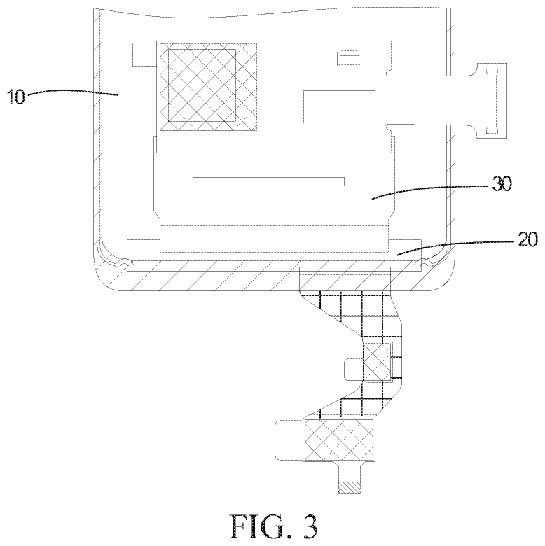

FIG. 3 is a structural schematic diagram showing that a bent portion 20 of the AMOLED panel according to the embodiment of the present disclosure is folded. Because an area of the second backing plate is less than that of the first backing plate, when the insulating substrate layer is folded, an orthographic projection area of the second backing plate all falls on a surface of the first backing plate facing the second backing plate. The hydrogel layer 50, coated on the bent portion 20 between the first backing plate 10 and the second backing plate 30, can increase structural strength of the bent portion 20 when the second backing plate 30 and the first backing plate 10 are in a folded state. Therefore, the bent portion 20 is not easily deformed, broken or cracked.

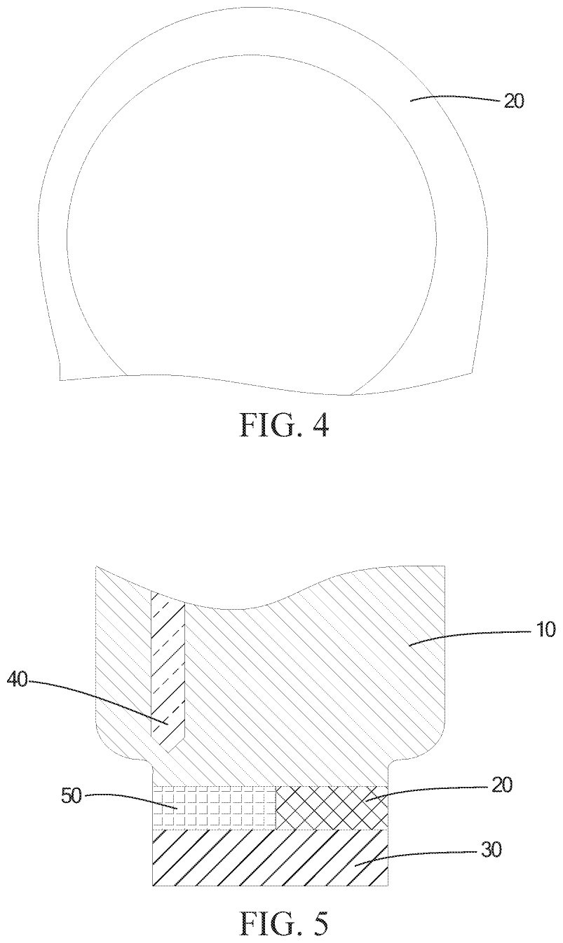

FIG. 4 is a schematic diagram of a fillet formed by folding bent portion 20 of the AMOLED panel according to the embodiment of the present disclosure. Since a bending angle of the fillet formed by folding the bent portion 20 may be up to 180 degrees, the fillet of the folded bent portion 20 will continue to be subjected to larger bending stress. However, the hydrogel layer 50, coated on the bent portion 20 between the first backing plate 10 and the second backing plate 30, can increase structural strength of the fillet of the bent portion 20. Therefore, the bent portion 20 is not easily deformed, broken or cracked.

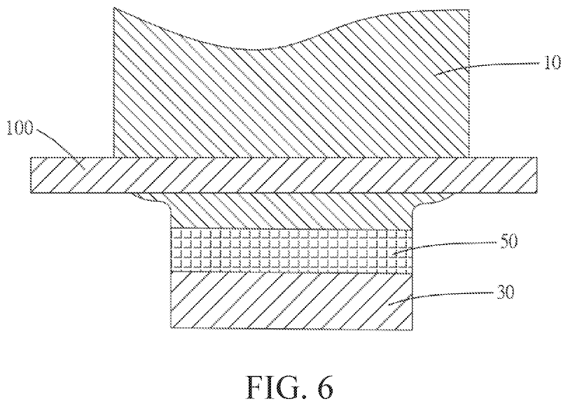

FIG. 5 is a schematic diagram showing that the bent portion of the AMOLED panel according to the embodiment of the present disclosure is coated with a hydrogel 50. FIG. 6 is a schematic diagram showing that the hydrogel layer 50 coated on the bent portion of the AMOLED panel according to the embodiment of the present disclosure is cured by an ultraviolet lamp. First, the hydrogel layer 50 is uniformly coated on the bent portion 20 between the second backing plate 30 and the first backing plate 10 by a hydrogel coating needle 40. Next, the hydrogel layer 50 is irradiated with UV light by a UV lamp 60 to cure the hydrogel layer 50. After the hydrogel layer 50 is cured by UV light irradiation, it can provide sufficient structural strength and toughness to the bent portion 20. Therefore, the bent portion 20 can maintain its structural strength and shape when it is folded. Finally, the first backing plate 10 and the second backing plate 30 are folded at the bent portion 20 to be in an installed state that can be installed in a product.

The present disclosure provides an AMOLED panel provided with a hydrogel layer on a bent portion between a first backing plate and a second backing plate. The hydrogel layer can increase structural strength and toughness of a fillet of the bent portion formed by folding the bent portion, Therefore, the bent portion can maintain its structural strength and shape when it is folded and is not easily deformed, broken or cracked, thereby improving the product quality and durability of the AMOLED panel.

The present disclosure has been disclosed in the above preferred embodiments, but the preferred embodiments are not intended to limit the present disclosure. Those skilled in the art can make various modifications to the above embodiments without departing from the technical idea of the present disclosure, and the modifications are all within the scope defined by the claims of the present disclosure.

What is claimed is:

1. An active matrix organic light emitting diode (AMOLED) panel, comprising:
an insulating substrate layer having a bent portion;
a first backing plate and a second backing plate disposed on the insulating substrate layer and separated by the bent portion;
a hydrogel layer coated on the bent portion between the first backing plate and the second backing plate;
an organic light emitting diode (OLED) layer disposed on a surface of the insulating substrate layer opposite to the surface on which the first backing plate and the second backing plate are disposed;
a touch plate optical clear adhesive layer disposed on a surface of the OLED layer opposite to the surface on which the insulating substrate layer is disposed;
a touch plate layer disposed on a surface of the touch plate optical clear adhesive layer opposite to the surface on which the OLED layer is disposed;
a polarizer layer disposed on a surface of the touch plate layer opposite to the surface on which the touch plate optical clear adhesive layer is disposed;
an optical clear adhesive layer disposed on a surface of the polarizer layer opposite to the surface on which the touch plate layer is disposed; and
a cover glass layer disposed on a surface of the optical clear adhesive layer opposite to the surface on which the polarizer layer is disposed.

2. The AMOLED panel according to claim 1, wherein an area of the second backing plate is less than that of the first backing plate, and when the insulating substrate layer is folded at the bent portion, an orthographic projection area of the second backing plate all falls on a surface of the first backing plate facing the second backing plate.

3. The AMOLED panel according to claim 2, wherein when the bent portion is in a folded state, its bending angle is 180 degrees.

4. The AMOLED panel according to claim 1, wherein the first backing plate and the second backing plate have a thickness of 95 μm.

5. The AMOLED panel according to claim 1, wherein the OLED layer further comprises a thin film transistor layer (TFT layer) and a thin film encapsulation layer (TFE layer).

6. The AMOLED panel according to claim 1, wherein the hydrogel layer has a thickness of 20-50 μm.

7. The AMOLED panel according to claim 1, wherein the insulating substrate layer is made of a polyimide (PI) material.

8. The AMOLED panel according to claim 1, wherein the hydrogel layer is made of a photocurable material.

9. The AMOLED panel according to claim 1, wherein the hydrogel layer is made of an ultraviolet curable material.

10. A method of manufacturing an active matrix organic light emitting diode (AMOLED) panel, wherein the AMOLED panel comprises:
an insulating substrate layer having a bent portion;
a first backing plate and a second backing plate disposed on the insulating substrate layer and separated by the bent portion;
a hydrogel layer coated on the bent portion between the first backing plate and the second backing plate;
an organic light emitting diode (OLED) layer disposed on a surface of the insulating substrate layer opposite to the surface on which the first backing plate and the second backing plate are disposed;
a touch plate optical clear adhesive layer disposed on a surface of the OLED layer opposite to the surface on which the insulating substrate layer is disposed;
a touch plate layer disposed on a surface of the touch plate optical clear adhesive layer opposite to the surface on which the OLED layer is disposed;
a polarizer layer disposed on a surface of the touch plate layer opposite to the surface on which the touch plate optical clear adhesive layer is disposed;
an optical clear adhesive layer disposed on a surface of the polarizer layer opposite to the surface on which the touch plate layer is disposed; and
a cover glass layer disposed on a surface of the optical clear adhesive layer opposite to the surface on which the polarizer layer is disposed; and
wherein the method comprises:
Step 1: uniformly coating the hydrogel layer on the bent portion between the first backing plate and the second backing plate;
Step 2: irradiating the hydrogel layer with ultraviolet to solidify the hydrogel layer;
Step 3: folding the first backing plate and the second backing plate deposited on the insulating substrate layer at the bent portion, such that a bending angle of the bent portion is 180 degrees when the bent portion is in a folded state.

11. The method of manufacturing the AMOLED panel according to claim 10, wherein an area of the second backing plate is less than that of the first backing plate, and when the insulating substrate layer is folded at the bent portion, an orthographic projection area of the second backing plate all falls on a surface of the first backing plate facing the second backing plate.

12. The method of manufacturing the AMOLED panel according to claim 10, wherein the first backing plate and the second backing plate have a thickness of 95 μm.

13. The method of manufacturing the AMOLED panel according to claim 10, wherein the OLED layer further comprises a thin film transistor layer (TFT layer) and a thin film encapsulation layer (TFE layer).

14. The method of manufacturing the AMOLED panel according to claim 10, wherein the hydrogel layer has a thickness of 20-50 μm.

15. The method of manufacturing the AMOLED panel according to claim 10, wherein the insulating substrate layer is made of a polyimide (PI) material.

16. The method of manufacturing the AMOLED panel according to claim 10, wherein the hydrogel layer is made of a photocurable material.

17. The method of manufacturing the AMOLED panel according to claim 10, wherein the hydrogel layer is made of an ultraviolet curable material.
